(19) United States
(12) Patent Application Publication
(10) Pub. No.: US 2019/0180791 A1
(43) Pub. Date: Jun. 13, 2019

(54) CHASSIS MONITORING SYSTEM AND CHASSIS MONITORING METHOD

(71) Applicant: Wistron Corporation, New Taipei City (TW)

(72) Inventors: Chih-Yuan Lin, New Taipei City (TW); Chih-Yuan Hung, New Taipei City (TW); Ming-Sheng Wu, New Taipei City (TW)

(73) Assignee: Wistron Corporation, New Taipei City (TW)

(21) Appl. No.: 15/909,976

(22) Filed: Mar. 1, 2018

(30) Foreign Application Priority Data
Dec. 12, 2017 (TW) 106143582

(51) Int. Cl. G11B 33/12; H05K 7/14

(52) U.S. Cl. CPC G11B 33/123; H05K 7/1435; H05K 7/1481

(57) ABSTRACT

A chassis monitoring system and a chassis monitoring method are provided. The chassis monitoring system includes an electronic device and a chassis including a SAS (serial attached SCSI) expander. The electronic device transmits a SES (SCSI Enclosure Service) command to the SAS expander through a TCP/IP (Transmission Control Protocol/Internet Protocol) protocol. The SAS expander executes the SES command to monitor the chassis. The SAS expander transmits an execution result of the SES command to the electronic device.

### CROSS-REFERENCE TO RELATED APPLICATION

This application claims the priority benefit of Taiwan application serial no. 106143582, filed on Dec. 12, 2017. The entirety of the above-mentioned patent application is hereby incorporated by reference herein and made a part of this specification.

### BACKGROUND OF THE INVENTION

### Field of the Invention

The invention relates to a chassis monitoring system and a chassis monitoring method, and particularly relates to a chassis monitoring system and a chassis monitoring method capable of reducing hardware cost and improving operation convenience.

### Description of Related Art

Generally, chassis used in enterprises may include a serial attached small computer systems interface (SCSI) expander (SAS expander) and several to dozens of hard disks coupled to the SAS expander. In order to monitor the chassis, a baseboard management controller (BMC) is generally disposed in the chassis for coupling to the SAS expander, for example, coupling to the SAS expander through an intelligent platform management bus (IPMB). A management personnel may use an application (for example, ipmitool) on an electronic device to connect the BMC through a network for monitoring a chassis state. However, the BMC cannot support an integral SCSI enclosure service (SES) specification, so that it is unable to obtain whole chassis information. Moreover, since a bandwidth between the BMC and the SAS expander is relatively small, information of the SAS expander cannot be obtained through the BMC in real-time. Last, a price of the BMC is rather high. Therefore, how to reduce the hardware cost to effectively monitor the chassis is a target to be achieved by related technicians of the field.

### SUMMARY OF THE INVENTION

The invention is directed to a chassis monitoring system and a chassis monitoring method, which is adapted to reduce hardware cost and effectively perform chassis monitoring.

The invention provides a chassis monitoring system including an electronic device and a chassis including a serial attached small computer systems interface (SCSI) expander (SAS expander). The electronic device is coupled to the SAS expander, and transmits a SCSI enclosure service (SES) command to the SAS expander through a transmission control protocol/Internet protocol (TCP/IP). The SAS expander executes the SES command to monitor the chassis. The SAS expander transmits an execution result of the SES command to the electronic device.

In an embodiment of the invention, the SAS expander creates a thread to determine whether a packet received by the SAS expander includes the SES command, and if the packet includes the SES command, the SAS expander executes the SES command and transmits the execution result to the electronic device through the thread.

In an embodiment of the invention, if the packet does not include the SES command, the SAS expander abandons the packet.

In an embodiment of the invention, the electronic device adds the SES command to a packet and transmits the packet to an Internet protocol (IP) address of the SAS expander.

In an embodiment of the invention, the chassis monitoring system further includes a server coupled to the electronic device and the SAS expander. The electronic devices logs in the server and transmits the SES command to the SAS expander through a transmission interface card of the server. The transmission interface card is a host bus adapter (HBA) interface card or a redundant array of independent disks (RAID) interface card.

In an embodiment of the invention, the SAS expander monitors the chassis to control the chassis or obtain chassis state information of the chassis.

The invention provides a chassis monitoring method, which is adapted to an electronic device and a chassis. The chassis includes a SAS expander, and the electronic device is coupled to the SAS expander. The chassis monitoring method includes transmitting a SES command to the SAS expander by the electronic device through a TCP/IP. The chassis monitoring method further includes executing the SES command by the SAS expander to monitor the chassis. The chassis monitoring method further includes transmitting an execution result of the SES command to the electronic device by the SAS expander.

In an embodiment of the invention, the SAS expander creates a thread to determine whether a packet received by the SAS expander includes the SES command, and if the packet includes the SES command, the SAS expander executes the SES command and transmits the execution result to the electronic device through the thread.

In an embodiment of the invention, if the packet does not include the SES command, the SAS expander abandons the packet.

In an embodiment of the invention, the electronic device adds the SES command to the packet and transmits the packet to an Internet protocol (IP) address of the SAS expander.

In an embodiment of the invention, the chassis monitoring system further includes a server coupled to the electronic device and the SAS expander. The electronic devices logs in the server and transmits the SES command to the SAS expander through a transmission interface card of the server. The transmission interface card is a host bus adapter (HBA) interface card or a redundant array of independent disks (RAID) interface card.

In an embodiment of the invention, the SAS expander monitors the chassis to control the chassis or obtain chassis state information of the chassis.

According to the above description, the chassis monitoring system and the chassis monitoring method of the invention may use the electronic device to directly transmit the SES command to the SAS expander in the chassis through the network to monitor the chassis and obtain a monitoring result without monitoring the chassis through an extra BMC, so that the whole chassis information is obtained without increasing extra hardware. Moreover, the chassis information may be transmitted to related application of the electronic device through the network in real-time.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a block diagram of a chassis monitoring system according to an embodiment of the invention.

FIG. 2 is a block diagram of a chassis monitoring system according to another embodiment of the invention.

FIG. 3 is a flowchart illustrating a chassis monitoring method according to an embodiment of the invention.

### DESCRIPTION OF EMBODIMENTS

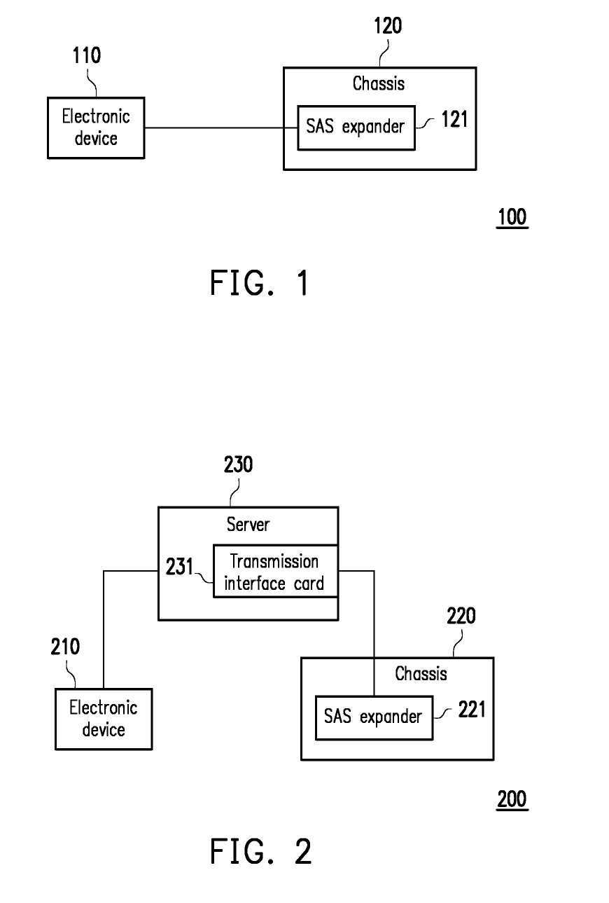

FIG. 1 is a block diagram of a chassis monitoring system according to an embodiment of the invention.

Referring to FIG. 1, the chassis monitoring system 100 of the present embodiment includes an electronic device 110 and a chassis 120. The electronic device 110 is, for example, a notebook or a personal computer (PC), and the electronic device 110 may communicate with the chassis 120 through a network. The chassis 120 includes a serial attached SCSI (SAS) expander 121 and a plurality of hard disks (not shown) coupled to the SAS expander 121.

The electronic device 110 may include a processor (not shown) and a memory (not shown). The processor may be a central processing unit (CPU), or other programmable general purpose or special purpose microprocessor, a digital signal processor (DSP), a programmable controller, an application specific integrated circuit (ASIC) or other similar device or a combination of the above devices. The memory may be any type of a fixed or movable random access memory (RAM), a read-only memory (ROM), a flash memory, a hard disk drive (HDD), a solid state drive (SSD) or similar device or a combination of the above devices.

In order to use the electronic device 110 to directly monitor the chassis 120, a service of SES over local area network (LAN) may be implemented in a firmware of the SAS expander 121, and the service of SES over LAN may also be implemented on an application of a driver of the electronic device 110.

To be specific, the electronic device 110 may place a SES command in a packet through an application and transmit the packet to an IP address of the SAS expander 121 through a TCP/IP. The SAS expander 121 may use the firmware to create a thread to determine whether the packet received by the SAS expander 121 includes the SES command, i.e. determine whether a payload in the packet is the SES data. If the packet includes the SES command, the SAS expander 121 may execute the SES command and transmit an execution result of the SES command to the electronic device 110 through the thread. If the packet does not include the SES command, the SAS expander 121 abandons the packet.

When the SAS expander 121 receives a SES packet including the SES command, the SAS expander 121 executes the SES command to monitor the chassis 120. The SES command may include a command instructing to obtain a chassis state such as a temperature, a voltage, etc. in the chassis 120, and may include a control command of the hard disks in the chassis 120, for example, a command for turning on/off the operation of the hard disks, etc., or a control command for controlling the chassis 120, for example, a command for controlling a rotation speed of a fan of the chassis 120. Namely, a management personnel may use the electronic device 110 to transmit the SES command to the SAS expander 121 to monitor the chassis 120, so as to control the chassis 120 and devices in the chassis 120 or obtain chassis state information of the chassis 120. Finally, an execution result of the SES command, for example, the transmitted back chassis state information or indication information for successfully stopping the operation of the hard disks is displayed through the application of the electronic device 110.

FIG. 2 is a block diagram of a chassis monitoring system according to another embodiment of the invention.

Referring to FIG. 2, the chassis monitoring system 200 of the invention includes an electronic device 210, a chassis 220 and a server 230. The electronic device 210 may be connected to the server 230 through a network, and a transmission interface card 231 of the server 230 may be coupled to a SAS expander 221 of the chassis 220 through a SAS transmission cable. The transmission interface card 231 may be the HBA interface card or the RAID interface card.

To be specific, the chassis management personnel may log in the server 230 through a secure shell (SSH), and use a related application in the server 230 to monitor the chassis 220. The user may directly input the SES command on the server 230 to monitor a state of the chassis 220. When the SAS expander 221 receives the SES command transmitted from the SAS transmission cable, the SAS expander 221 executes the SES command to monitor the chassis 220, and transmits the execution result corresponding to the SES command back to the server 230.

The SES command may include a command instructing to obtain a chassis state such as a temperature, a voltage, etc. in the chassis 220, and may include a control command of the hard disks in the chassis 220, for example, a command for turning on/off the operation of the hard disks, etc., or a control command for controlling the chassis 220, for example, a command for controlling a rotation speed of a fan of the chassis 220. Namely, a management personnel may use the server 230 to transmit the SES command to the SAS expander 221 to monitor the chassis 220, so as to control the chassis 220 and devices in the chassis 220 or obtain chassis state information of the chassis 220. Finally, an execution result of the SES command, for example, the transmitted back chassis state information or indication information for successfully stopping the operation of the hard disks is transmitted back to the server 230 for providing to the user.

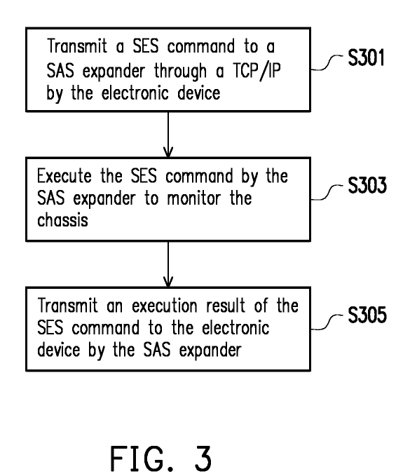

FIG. 3 is a flowchart illustrating a chassis monitoring method according to an embodiment of the invention.

Referring to FIG. 3, in step S301, an electronic device is applied to transmit a SES command to an SAS expander through a TCP/IP.

In step S303, the SAS expander is applied to execute the SES command to monitor the chassis.

In step S305, the SAS expander is applied to transmit an execution result of the SES command to the electronic device.

In summary, the chassis monitoring system and the chassis monitoring method of the invention may use the electronic device to directly transmit the SES command to the SAS expander in the chassis through the network to monitor the chassis and obtain a monitoring result without monitoring the chassis through an extra BMC, so that the whole chassis information is obtained without increasing extra hardware. The chassis information may be transmitted to related application of the electronic device through the network in real-time. Moreover, the chassis monitoring system and the chassis monitoring method of the invention implement the service of SES over LAN in the firmware of the SAS expander, a notebook may be directly connected to the SAS expander through the network to use the whole SES service, which greatly decreases the hardware cost of the chassis and greatly improve chassis monitoring efficiency and operation convenience.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

1. A chassis monitoring system, comprising:
an electronic device; and
a chassis, comprising a serial attached small computer systems interface (SCSI) expander (SAS expander), the electronic device coupling to the SAS expander, wherein
the electronic device transmits a SCSI enclosure service (SES) command to the SAS expander through a transmission control protocol/Internet protocol (TCP/IP),
the SAS expander executes the SES command to monitor the chassis, and
the SAS expander transmits an execution result of the SES command to the electronic device;
wherein the SAS expander creates a thread to determine whether a packet received by the SAS expander comprises the SES command, and if the packet comprises the SES command, the SAS expander executes the SES command and transmits the execution result to the electronic device through the thread.

2. (canceled)

3. The chassis monitoring system as claimed in claim 1, wherein if the packet does not comprise the SES command, the SAS expander abandons the packet.

4. The chassis monitoring system as claimed in claim 1, wherein the electronic device adds the SES command to a packet and transmits the packet to an Internet protocol (IP) address of the SAS expander.

5. The chassis monitoring system as claimed in claim 1, further comprising a server coupled to the electronic device and the SAS expander, wherein the electronic devices logs in the server and transmits the SES command to the SAS expander through a transmission interface card of the server, wherein the transmission interface card is a host bus adapter (HBA) interface card or a redundant array of independent disks (RAID) interface card.

6. The chassis monitoring system as claimed in claim 1, wherein the SAS expander monitors the chassis to control the chassis or obtain chassis state information of the chassis.

7. A chassis monitoring method, adapted to an electronic device and a chassis, the chassis comprising a SAS expander, and the electronic device being coupled to the SAS expander, the chassis monitoring method comprising:
transmitting a SES command to the SAS expander by the electronic device through a TCP/IP;
executing the SES command by the SAS expander to monitor the chassis; and
transmitting an execution result of the SES command to the electronic device by the SAS expander;
wherein the SAS expander creates a thread to determine whether a packet received by the SAS expander comprises the SES command, and if the packet comprises the SES command, the SAS expander executes the SES command and transmits the execution result to the electronic device through the thread.

8. (canceled)

9. The chassis monitoring method as claimed in claim 7, wherein if the packet does not comprise the SES command, the SAS expander abandons the packet.

10. The chassis monitoring method as claimed in claim 7, wherein the electronic device adds the SES command to the packet and transmits the packet to an Internet protocol (IP) address of the SAS expander.

11. The chassis monitoring method as claimed in claim 7, further comprising logging in a server through the electronic device and transmitting the SES command to the SAS expander through a transmission interface card of the server, wherein the transmission interface card is a host bus adapter (HBA) interface card or a redundant array of independent disks (RAID) interface card.

12. The chassis monitoring method as claimed in claim 7, wherein the SAS expander monitors the chassis to control the chassis or obtain chassis state information of the chassis.
